(19) United States
(12) Patent Application Publication
(10) Pub. No.: US 2025/0253281 A1
(43) Pub. Date: Aug. 7, 2025

(54) Through-substrate laser soldering with embedded absorbing layer

(71) Applicant: Apple Inc., Cupertino, CA (US)

(72) Inventors: Jeremy D. Witmer, San Jose, CA (US); Jeffrey T. Hill, Santa Clara, CA (US); Yipin Wu, Los Altos, CA (US)

(21) Appl. No.: 18/432,609

(22) Filed: Feb. 5, 2024

(51) Int. Cl. H01L 23/00; H01L 25/10

(52) U.S. Cl. CPC H01L 24/32; H01L 25/105; H01L 2224/32145

(57) ABSTRACT

Electronic assemblies with absorbing layers are described. In an embodiment, an electronic assembly includes an absorbing layer embedded in a substrate, a landing pad formed on a top surface of the substrate, and an electronic component bonded to the landing pad by a bonding layer, where the absorbing layer is located below the electronic component and absorbs a particular wavelength to a greater extent than the substrate.

### BACKGROUND

### Field

Embodiments described herein relate to microelectronic packaging techniques, and more particularly to photonic soldering.

### Background Information

Microelectronic packaging has widely adopted soldering technology for the bonding of electronic components. Selective soldering techniques have been adopted in some applications to avoid high temperature exposure to the electronic component being bonded, the substrate, or adjacent components. One such selective soldering technique, laser soldering, is a widely adopted conventional die attach technique. Typically, the bottom of a substrate absorbs laser light, the heat from the laser light diffuses upwards and eventually reaches the top surface of the substrate, melting the solder material.

### SUMMARY

Embodiments describe electronic assemblies and methods in which an absorbing layer is embedded in a substrate for laser soldering processes. In an embodiment, the absorbing layer may be embedded in the substrate, where the absorbing layer absorbs a particular wavelength to a greater extent than the substrate so that heat dissipated from the absorbing layer may heat a bonding layer to bond an electronic component to the substrate. In some instances, the substrate may include a waveguide and a buried oxide layer, where the substrate is structured so that a light path of the electronic component bonded to the substrate aligns with the waveguide. In an embodiment, an array of electronic assemblies may include a first electronic assembly with a first absorbing layer that absorbs a first wavelength to a greater extent than the substrate, and a second electronic assembly with a second absorbing layer that absorbs a second wavelength to a greater extent than the substrate.

### BRIEF DESCRIPTION OF THE DRAWINGS

FIG. 1A is a cross sectional side view illustration of an electronic assembly that includes an absorbing layer in accordance with embodiments.

FIG. 1B is a cross sectional side view illustration of an electronic assembly that includes an absorbing layer and an anti-reflective coating in accordance with embodiments.

FIG. 1C is a cross sectional side view illustration of an electronic assembly that includes a patterned absorbing layer in accordance with embodiments.

FIG. 2A is a cross sectional side view illustration of an electronic assembly with a patterned absorbing layer and an embedded lateral insulating layer in accordance with embodiments.

FIG. 2B is a cross sectional side view illustration of an electronic assembly with a patterned absorbing layer, an embedded lateral insulating layer and insulating walls in accordance with embodiments.

FIG. 2C is schematic top view illustration of an array of electronic assemblies with patterned absorbing layers, an embedded lateral insulating layer and insulating walls in accordance with an embodiment.

FIG. 3A is a cross sectional side view illustration of multiple electronic assemblies with different patterned absorbing layers in accordance with embodiments.

FIG. 3B is a cross sectional side view illustration of multiple electronic assemblies with different patterned absorbing layers in accordance with embodiments.

FIG. 3C is a cross sectional side view illustration of multiple electronic assemblies with different patterned absorbing layers on different planes in accordance with embodiments.

FIG. 4A is a cross sectional side view illustration of an electronic assembly that includes an absorbing layer in accordance with embodiments.

FIG. 4B is a cross sectional side view illustration of an electronic assembly that includes an absorbing layer and an insulating layer in accordance with embodiments.

FIG. 5 is a flow chart of a method of forming an exemplary absorbing layer in accordance with an embodiment.

FIG. 6A-6B are schematic cross-sectional side view illustrations of a method of embedding an exemplary absorbing layer in a substrate in accordance with an embodiment.

### DETAILED DESCRIPTION

In one aspect, it has been observed that photonic devices (e.g., photonic integrated circuits, etc.) require even greater precision in the die bonding process than traditional electronic devices in order to minimize light scattering, maximize coupling efficiency, and meet other narrow performance requirements. In one aspect, it has been observed that laser soldering is well-suited for photonics die bonding applications due to its micron-level x-y die alignment. While laser soldering may provide micron-level accuracy, heat spreading throughout the substrate is not without its limitations. For example, heat spreading throughout the substrate can cause soldering from a neighboring die to reflow and potentially affect the alignment of the neighboring die, which effectively limits the minimum pitch between neighboring dies. In addition, heat spreading through the substrate takes time to diffuse upwards, which may increase the soldering cycle time. Heat spreading may also cause thermal expansion of the substrate itself, which may affect die alignment if not compensated for. Recent approaches in laser soldering tune the wavelength of the laser light so that, rather than being absorbed by the substrate and causing the heat spreading issues discussed above, the laser light passes through the substrate and becomes absorbed by the top metal layer formed over the substrate rather than the substrate itself. However, the high-powered lasers utilized in such approaches may damage the optical characteristics of the die. In addition, such approaches may not be efficient due to the high reflectivity of the metal layer (e.g., 90% for gold metallization).

In accordance with embodiments, electronic assemblies are described that include a substrate with an embedded absorbing layer, where the band-gap of the absorbing layer has been tuned to absorb a particular wavelength to a greater extent than the surrounding substrate (e.g., wavelength larger than about 1100 nm). In such instances, the light source may pass through a lower layer of the substrate and then become absorbed by the absorbing layer, which diffuses the heat over a shorter, more localized upper layer of the substrate. In this way, the localized heating provided by the absorbing layer decouples the heating profile from electrical design of an array of dies to minimum pitch size, reduces the thermal expansion of the substrate, and increases the bonding speed of the soldering cycle.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known semiconductor processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “above”, “over”, “to”, “between”, “spanning” and “on” as used herein may refer to a relative position of one layer with respect to other layers. One layer “above”, “over”, “spanning” or “on” another layer or bonded “to” or in “contact” with another layer may be directly in contact with the other layer or may have one or more intervening layers. One layer “between” layers may be directly in contact with the layers or may have one or more intervening layers.

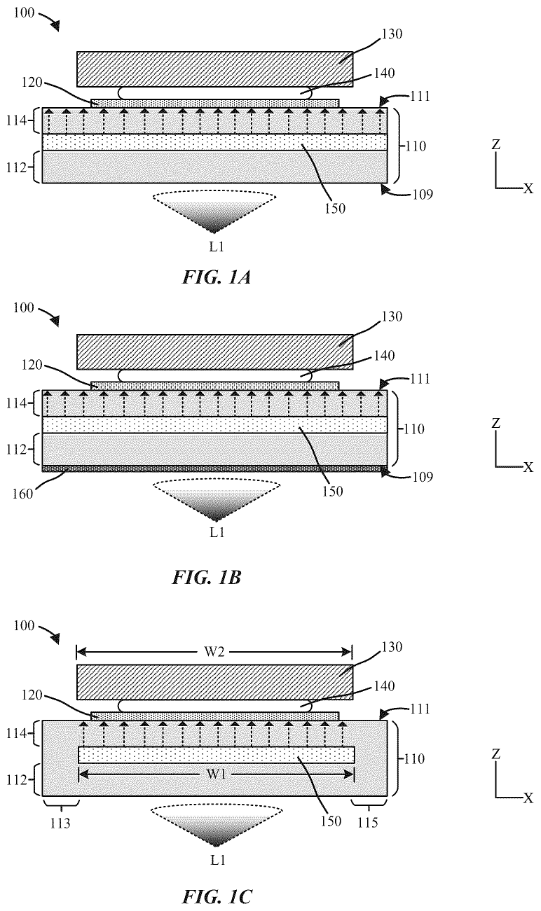

Referring now to FIG. 1A, a cross sectional side view illustration is provided of an electronic assembly with an absorbing layer for through-substrate soldering in accordance with embodiments. Electronic assembly 100 includes substrate 110, landing pad 120 formed on top surface 111 of substrate 110, where electronic component 130 is bonded to landing pad 120 by a bonding layer 140. Substrate 110 may be formed of semiconductor material, such as silicon, or other suitable materials, such as glass, indium phosphide, gallium arsenide, lithium niobate, etc. In addition, substrate 110 as illustrated in FIG. 1A may only represent a portion of a larger wafer (e.g., “8 inch” wafer with 725 micron thickness, “12 inch” wafer with 775 micron thickness, etc.), where the larger wafer may include an array of multiple other electronic components soldered or otherwise affixed to its top surface in addition to electronic component 130. In embodiments where the substrate is glass, a larger glass panel may undergo glass panel processing techniques to yield substrate 110. Landing pad 120 may be formed of a thermally conductive metallic material(s) so that heat may be transferred from substrate 110 to bonding layer 140, where landing pad 120 can be a single layer or multiple layers (e.g., under bump metallurgy). Electronic component 130 may include various photonics dies or devices related to the emission, transmission, amplification, detection and modulation of light, such as photonic integrated circuits, optical modulators, photodetectors, optical amplifiers, light sources (e.g., light emitting diodes, lasers, etc.), as well as other dies or devices. In the example of FIG. 1A, electronic component 130 is a III-V laser die. Further, bonding layer 140 can be formed of a suitable material. For example, where electrical conductivity is required, bonding layer 140 can be an electrically conductive bonding material such as solder (e.g., gold-tin solder, etc.), conductive (filled) polymer such as epoxy, etc. In some instances, bonding may not require an electrical connection, and bonding layer 140 may be formed of suitable material such as epoxy, etc. In such instances, the epoxy material can be heat-curable and may be cured during an attach process (e.g., optical die attach process, display attach process, etc.), where the heat-curable epoxy is transparent. In other embodiments, specific sections of the bonding layer (e.g., edges, corners, etc.) may be heated in a specific order (e.g., edges first, corners first, etc.) to control potential warpage of the die during the soldering process.

Electronic assembly 100 also includes absorbing layer 150 embedded in substrate 110, where a band-gap of absorbing layer 150 may be tuned to absorb a particular wavelength to a greater extent than substrate 110. Absorbing layer 150 may be formed of semiconductor material (e.g. silicon germanium), narrow-gap semiconductor material (e.g., mercury cadmium telluride, indium arsenide, etc.), or metals (e.g., Pb, Ti, etc.). In a particular embodiment, absorbing layer 150 may be formed of silicon germanium, SiₓGe₁₋ₓ, which has good coefficient of thermal expansion (“CTE”) matching with silicon and has a band-gap that may be tuned between 0.7 eV (˜1770 nm) and 1.1 eV (˜1100 nm) so that a light source (e.g., laser) that operates at a particular wavelength may be absorbed by the absorbing layer and converted into heat for the soldering process. Silicon germanium may be grown epitaxially on silicon substrates. In addition, silicon may be epitaxially regrown on top of silicon germanium, where a new top surface may be formed (e.g., top surface 111 of substrate 110), or where additional wafer fabrication techniques may be performed (e.g., silicon on insulator (SOI) fabrication techniques, etc.). Further, absorbing layer 150 may be located in close proximity to the top surface of the substrate in order to prevent heat spreading to a neighboring die, reduce the time for the heat to diffuse upward, and limit thermal expansion of the substrate. In the example of FIG. 1A, absorbing layer 150 is an SiGe layer with a band-gap of 0.8 eV (˜1550 nm), where a light source, L1, with a wavelength of 1500 nm passes through lower layer 112 of substrate 110 without being absorbed until L1 reaches absorbing layer 150, where L1 becomes absorbed by absorbing layer 150. Further, heat diffuses from absorbing layer 150 through upper layer 114 of substrate 110 and landing pad 120 in order to melt bonding layer 140. In some embodiments, the bottom surface of the substrate may be coated with an anti-reflective coating (e.g., silicon nitride, tantalum oxide, etc.) in order to reduce reflection by the bottom surface of the substrate. For example, in FIG. 1B, bottom surface 109 of substrate 110 includes anti-reflective coating 160. In such instances, anti-reflective coating 160 may be applied so that a thickness of the anti-reflective coating is a quarter wavelength of the light source wavelength. In other embodiments, the light source may be applied through top surface 111 of substrate 110 to accommodate a particular die geometry or manufacturing need.

Referring now to FIG. 1C, a cross sectional side view illustration is provided of an electronic assembly with a patterned absorbing layer for through-substrate soldering in accordance with embodiments. Referring back to the examples of FIG. 1A-1B, absorbing layer 150 is continuous in that the absorbing layer spans from one side of substrate 110 to the other side. In some embodiments, an absorbing layer may be continuous in that it spans across an entirety of the silicon wafer, or substrate diced therefrom. In other embodiments, such as the example of FIG. 1C, an absorbing layer may be patterned to span across only a portion of the silicon wafer. More specifically, the absorbing layer may be patterned to correspond to one die or a group of dies to be affixed to the substrate above. For example, absorbing layer 150 in the example of FIG. 1C is patterned, where the patterning may be performed by lithography or shadow masking during deposition, or by laser patterning post deposition, etc. and combinations thereof. In such instances, the absorbing layer may be patterned to any shape or dimension, and to underlie any number of devices or dies to be affixed to top surface 111 of substrate 110. For example, absorbing layers may be patterned to approximate the shape and dimensions of a die to be attached to a surface above the absorbing layer, to span only a certain percentage of the die footprint (e.g. 50%, etc.), to span multiple devices or dies, etc. In the example of FIG. 1C, absorbing layer 150 is patterned so that a width, W1, of absorbing layer 150 is of the same or similar width as a width, W2, of electronic component 130. In further reference to FIG. 1C, during the laser soldering process, a light source, L1, may pass through intermediate layers 113, 115 but may become absorbed by absorbing layer 150, which then diffuses heat into upper layer 114 of substrate 110. The heat dissipating from the patterned absorbing layer is more precisely localized to the region directly below electronic component 130 (e.g., width W1), as opposed to the example of FIG. 1A in which the heat from the continuous absorbing layer is more widely diffused. In this way, the selective heating of localized areas on the substrate may be achieved when using a defocused light source as opposed to a focused laser spot so that the soldering process may rely more on the geometry of the patterned absorbing layer rather than the particular light source applied.

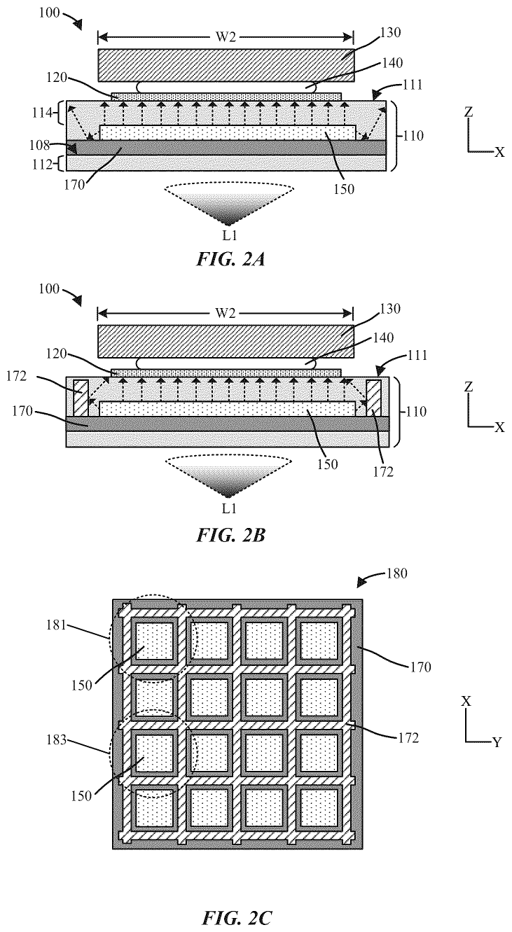

Referring now to FIG. 2A, a cross sectional side view illustration is provided of an electronic assembly with a patterned absorbing layer and an embedded lateral insulating layer in accordance with embodiments. Embedded insulating layers may be located below and around the absorbing layers in order to “trap” the heat diffused from the absorbing layers near the top surface of the substrate, where the insulating layers may be structured to confine the heat laterally as well as vertically. Further, such insulating layers may be formed by typical SOI wafer fabrication techniques, such as separation by implantation of oxygen or “SIMOX”, wafer bonding (e.g., Smart Cut, NanoCleave, etc.), etc., in which an insulating layer (e.g., silicon oxide, etc.) may be formed over a bare silicon wafer and then subsequent layers (e.g., silicon, silicon germanium, etc.) may then be formed and/or patterned over the insulating layer. For example, absorbing layers may be formed and/or patterned over the insulating layer to form any shape or dimension (e.g., shape or dimension of a die to be attached above, etc.), and to underlie any number of devices or dies to be affixed to top surface 111 of substrate 110. In the example of FIG. 2A, lateral insulating layer 170 may be formed over top surface 108 of a bare silicon wafer, where the lateral insulating layer 170 may be continuous and span across a width of the bare silicon wafer or substrate diced therefrom. Further, absorbing layer 150 may then be subsequently patterned over lateral insulating layer 170, where the shape and dimensions of the patterned absorbing layer may approximate the shape and dimensions of electronic component 130. In one example, a light source, L1, with a wavelength of 1500 nm passes through lower layer 112 of substrate 110 (e.g., silicon) and lateral insulating layer 170 (e.g., silicon oxide), and then becomes absorbed by absorbing layer 150 (e.g., silicon germanium) with a band-gap that has been tuned to 0.8 eV (˜1550 nm). Further, heat may then diffuse from absorbing layer 150 through upper layer 114 of substrate 110 and landing pad 120 in order to melt bonding layer 140. In addition, lateral insulating layer 170 may confine or redirect the diffused heat to upper layer 114 by acting as an insulative barrier below absorbing layer 150.

Referring now to FIG. 2B, a cross sectional side view illustration is provided of an electronic assembly with a patterned absorbing layer, an embedded lateral insulating layer and insulating walls in accordance with embodiments. In the example of FIG. 2B, insulating walls 172 may be a continuous layer or grid structure formed over lateral insulating layer 170 to further confine the diffused heat to the region directly above insulating layer 150. It should be noted that the example of FIG. 2B shows insulating walls 172 on either side of absorbing layer 150 so that absorbing layer 150 may be visible in the illustration. In practice, the insulating walls form “streets” that may laterally surround the absorbing layer on all sides to create an isolated “cell” or “island” where the grid structure of insulating walls 172 may create cells or islands for the other insulating layers in the array as well. For example, in FIG. 2C, cell 181 in array 180 (e.g., micro-LED array, pixel array, etc.) includes absorbing layer 150, which is formed over lateral insulating layer 170 and surrounded by insulating walls 172, which may form other cells that surround other insulating layers in the array, such as insulating layer 150 in cell 183. In some embodiments, the band-gap of the absorbing layers in an array may be tuned to absorb the same or similar wavelength and May include the same or similar electronic components or dies mounted above. In other embodiments, the band-gap of the absorbing layers in an array may be tuned to absorb different wavelengths and may include different electronic components or dies mounted above. Utilizing insulating layers in this manner may further localize heating, which may provide finer control of the soldering process, reduce the minimum pitch on an array, and lower the energy required for soldering.

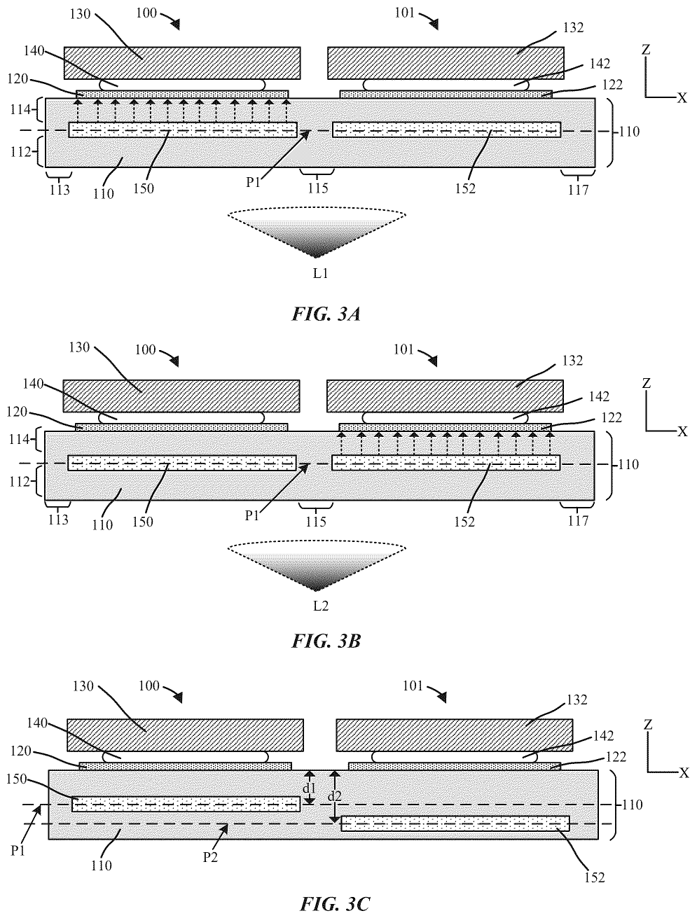

Referring now to FIG. 3A, a cross sectional side view illustration is provided of an array of multiple electronic assemblies with different patterned absorbing layers in accordance with embodiments. In practice, multiple different absorbing layers may be included in an array of multiple different die types. For example, the band-gap of silicon germanium absorbing layers may be tuned to absorb a variety of different wavelengths due to its widely adjustable band-gap so that the composition of neighboring absorbing layers may be the same or different. In the example of FIG. 3A, absorbing layer 150 is a SiGe layer with a band-gap of 0.8 eV (˜1550 nm) whereas its neighboring absorbing layer, absorbing layer 152, is a SiGe layer with a band-gap of 0.9 eV (˜1380 nm). While the example of FIG. 3A includes two different absorbing layers with two different band-gaps, it is contemplated in other embodiments that multiple different absorbing layers (more than two) composed of multiple different materials (e.g., semiconductor material, narrow band-gap semiconductor material, metal, etc.) may also be included in the same array to suit manufacturing needs.

In the example of FIG. 3A, a first light source, L1, with a wavelength of 1500 nm passes through lower layer 112, and intermediate layers 113, 115, 117 but becomes absorbed by absorbing layer 150, where heat diffuses through upper layer 114 above absorbing layer 150 to landing pad 120 in order to melt bonding layer 140. However, L1 does not become absorbed by absorbing layer 152 due to the mismatch of the wavelength of L1 (1500 nm) and the composition of absorbing layer 152 (tuned for 1380 nm laser). Referring now to the example of FIG. 3B, a second light source, L2, with a wavelength of 1300 nm becomes absorbed by absorbing layer 152, where heat diffuses through upper layer 114 above absorbing layer 152 to landing pad 122 in order to melt soldering material 142. As shown in FIGS. 3A-3B, the different absorbing layers are located on the same plane, P1. In other embodiments, the different absorbing layers may be located on different planes, such as the example provided in FIG. 3C, where absorbing layer 150 is located on plane P1 and absorbing layer 152 is located on plane P2 such that the different absorbing layers may be located at different depths within the substrate or different distances from their corresponding landing pads. For example, in FIG. 3C, plane P1 is located a distance d1 from landing pad 120, and plane P2 is located a distance d2 from landing pad 122, where d2 is greater than d1. By embedding multiple different absorbing layers into the same substrate, multiple different heating lasers (with multiple different wavelengths) may be used in conjunction with the different absorbing layers to selectively heat the different absorbing layers, which allows for the soldering of different die types within a tight pitch.

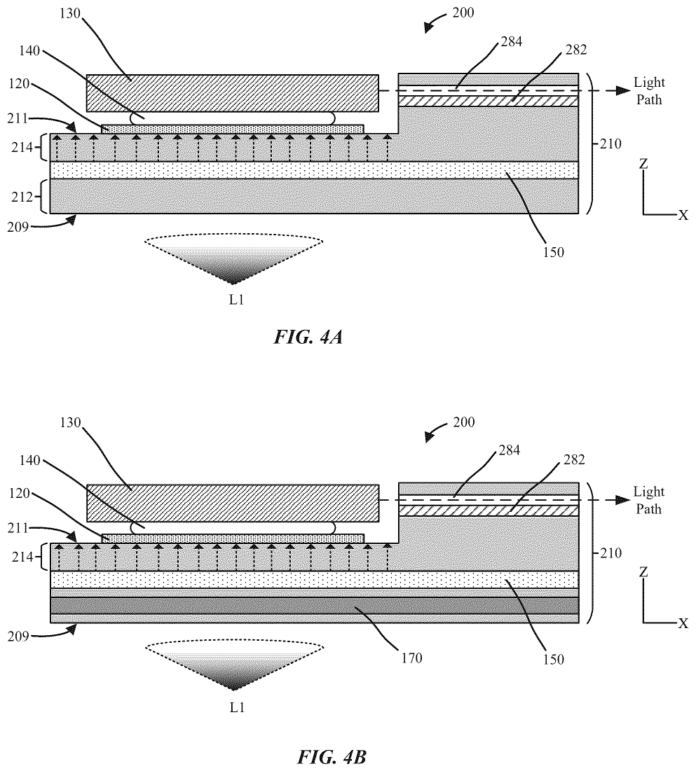

Referring now to FIG. 4A, a cross sectional side view illustration is provided of an electronic assembly with an absorbing layer for through-substrate soldering in accordance with embodiments. In some embodiments, an electronic assembly may include a waveguide embedded in the substrate, where the substrate is structured so that a light path of the electronic component mounted on the substrate aligns with the waveguide. For example, as illustrated in FIG. 4A, electronic assembly 200 includes substrate 210, landing pad 120 formed on a top surface 211 of substrate 210, where electronic component 130 is bonded to landing pad 120 by bonding layer 140. In addition, substrate 210 includes waveguide 284 (e.g., silicon waveguide, etc.) and buried oxide layer 282 (e.g., silicon oxide), where waveguide 284 confines and directs light propagated from electronic component 130 (e.g., III-V laser) and buried oxide layer 282 acts as a barrier layer to prevent the leakage of light into substrate 210. In addition, electronic assembly 200 may be structured so that a path of the light propagated from electronic component 130 aligns precisely (e.g., submicron alignment) with waveguide 284 in the z-direction. With regard to the x-y directions, submicron alignment may be achieved by utilizing a camera system, where thermal waves produced during soldering may interfere with or disturb the alignment process of the camera system. To minimize such thermal effects, substrate 210 may further include absorbing layer 150, which minimizes the amount of energy required to heat bonding layer 140 and also localizes the thermal effects of the soldering process. In the example of FIG. 4A, a light source, L1, with a wavelength of 1500 nm passes through lower layer 212 of substrate 210 and then becomes absorbed by absorbing layer 150 (e.g., silicon germanium) with a band-gap tuned to 0.8 eV (˜1550 nm). Further, heat may then diffuse from absorbing layer 150 through upper layer 214 of substrate 210 and landing pad 120 in order to melt bonding layer 140. In some embodiments, electronic assembly 200 may also include lateral insulating layer 170 to further minimize the thermal requirements for the soldering process and further localize its thermal effects, as illustrated in the example of FIG. 4B.

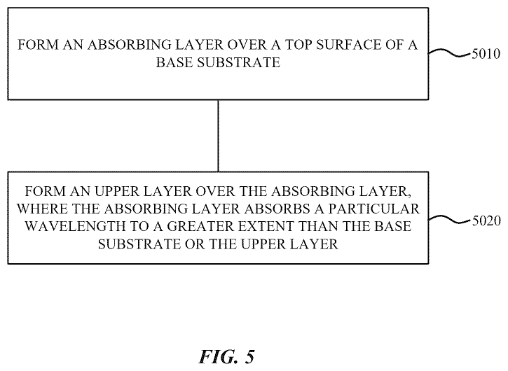

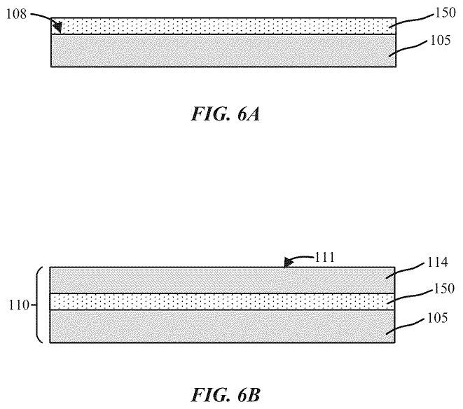

FIG. 5 is a flow chart and FIGS. 6A-6B are schematic cross-sectional side view illustrations of a method of embedding an absorbing layer in accordance with embodiments. In the interest of clarity and conciseness, the method of FIG. 5 is described concurrently with the illustrations of FIGS. 6A-6B. At operation 5010, an absorbing layer (e.g., absorbing layer 150, etc.) may be formed over a base or bare substrate (e.g., silicon wafer, glass panel, etc.), where the base or bare substrate may include lower layer 112, lower layer 212, etc. In an embodiment, silicon germanium may be epitaxially grown over a bare silicon wafer 105, where the band-gap of silicon germanium may be tuned to absorb a particular wavelength. In addition, the absorbing layer may be continuous, as illustrated in FIG. 6A, or patterned to form any shape such as a geometry that corresponds to a geometry of the electronic component or die to be mounted above, for example. Further, multiple adjacent absorbing layers may be patterned to include the same or different compositions, such as absorbing layers, 150, 152 in FIG. 3A. At operation 5020, upper layer 114 (e.g., silicon layer, etc.) may be formed over the absorbing layer to form top surface 111 of substrate 110, where the upper layer may be epitaxially grown or amorphous. In some embodiments, such as the embodiment described in FIG. 1A, assembly steps may then be performed over top surface 111 of substrate 110, such as applying metal landing pad 120, depositing bonding layer 140, etc. In other embodiments, additional wafer processing steps may be required to embed supplemental layers within the substrate before the assembly steps may be performed, such as lateral insulating layer 170 and insulating walls 172 described in FIG. 2B, or buried oxide layer 282 and waveguide 284 described in FIG. 4B. It should be noted that the insulating layers (e.g., lateral insulating layer 170, insulating walls 172, etc.) and the buried oxide layers (e.g., buried oxide layer 282, etc.) may be formed of the same or similar material (e.g., SiO₂) yet they may perform different functions due to their locations within the substrate. For example, the insulating layers perform an insulative function near and around the absorbing layer, whereas the buried oxide layer prevents light leakage from the waveguide into the substrate. As such, these SiO₂-based layers may be produced by typical SOI wafer fabrication techniques, such as separation by implantation of oxygen or “SIMOX”, wafer bonding (e.g., Smart Cut, NanoCleave, etc.), seed methods, etc., after which the assembly steps (e.g., apply metal landing pads, depositing solder, etc.) may then be performed.

In utilizing the various aspects of the embodiments, it would become apparent to one skilled in the art that combinations or variations of the above embodiments are possible for electronic assemblies that include a substrate with an embedded absorbing layer. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. An electronic assembly comprising:
a substrate;
an absorbing layer embedded in the substrate;
a landing pad formed on a top surface of the substrate; and
an electronic component bonded to the landing pad by a bonding layer;
wherein the absorbing layer is located below the electronic component and absorbs a particular wavelength to a greater extent than the substrate.

2. The electronic assembly of claim 1, wherein the substrate comprises silicon.

3. The electronic assembly of claim 1, wherein the absorbing layer comprises silicon germanium.

4. The electronic assembly of claim 1, wherein the bonding layer comprises an electrically conductive material.

5. The electronic assembly of claim 1, wherein the absorbing layer is continuous.

6. The electronic assembly of claim 1, wherein the absorbing layer is patterned to approximate a shape of the electronic component.

7. The electronic assembly of claim 1, wherein a bottom surface of the substrate includes an anti-reflective coating.

8. The electronic assembly of claim 1, further comprising a lateral insulating layer located below the absorbing layer.

9. The electronic assembly of claim 8, further comprising insulating walls formed over the lateral insulating layer, wherein the insulating walls create a cell that laterally surrounds the absorbing layer.

10. The electronic assembly of claim 1, wherein the substrate includes a waveguide and a buried oxide layer, the waveguide being located over the buried oxide layer.

11. The electronic assembly of claim 10, wherein the substrate is structured so that a light path of the electronic component aligns with the waveguide.

12. The electronic assembly of claim 11, wherein the substrate includes a lateral insulating layer located below the absorbing layer.

13. An array of electronic assemblies comprising:
a first electronic assembly including:
a substrate;
a first absorbing layer embedded in the substrate;
a first landing pad formed on a top surface of the substrate; and
a first electronic component bonded to the first landing pad by a first bonding layer;
wherein the first absorbing layer is located below the first electronic component and absorbs a first wavelength to a greater extent than the substrate; and
a second electronic assembly including:
a second absorbing layer embedding in the substrate;
a second landing pad formed on the top surface of the substrate; and
a second electronic component bonded to the second landing pad by a second bonding layer;
wherein the second absorbing layer is located below the second electronic component and absorbs a second wavelength to a greater extent than the substrate.

14. The array of claim 13, further comprising a lateral insulating layer located below the first and second absorbing layers, wherein the lateral insulating layer spans across a width of the substrate.

15. The array of claim 14, further comprising insulating walls formed over the lateral insulating layer, wherein the insulating walls create a first cell that laterally surrounds the first absorbing layer, and a second cell that laterally surrounds the second absorbing layer.

16. The array of claim 13, wherein the first absorbing layer and the second absorbing layer are located on a same plane.

17. A method for embedding an absorbing layer in a substrate comprising:
forming the absorbing layer over a top surface of a base substrate; and
forming an upper layer over the absorbing layer;
wherein the absorbing layer absorbs a particular wavelength to a greater extent than the base substrate or the upper layer.

18. The method of claim 17, wherein the upper layer comprises silicon.

19. The method of claim 17, wherein the absorbing layer comprises silicon germanium.

20. The method of claim 17, further comprising forming a buried oxide layer over the upper layer, and a waveguide over the buried oxide layer.
